(19) United States
(12) Patent Application Publication
(10) Pub. No.: US 2019/0109187 A1
(43) Pub. Date: Apr. 11, 2019

(54) SEMICONDUCTOR SWITCHING ELEMENT

(71) Applicants: TOYOTA JIDOSHA KABUSHIKI KAISHA, Toyota-shi, Aichi-ken (JP); DENSO CORPORATION, Kariya-city, Aichi-pref. (JP)

(72) Inventors: Tadashi MISUMI, Nisshin-shi (JP); Hiroomi EGUCHI, Seto-shi (JP); Yusuke YAMASHITA, Nagakute-shi (JP); Yasushi URAKAMI, Kariya-shi (JP)

(73) Assignees: TOYOTA JIDOSHA KABUSHIKI KAISHA, Toyota-shi, Aichi-ken (JP); DENSO CORPORATION, Kariya-city, Aichi-pref. (JP)

(21) Appl. No.: 16/093,882

(22) PCT Filed: Apr. 18, 2017
(86) PCT No.: PCT/IB2017/000425

§ 371 Date: Oct. 15, 2018

(30) Foreign Application Priority Data
Apr. 18, 2016 (JP) 2016-082975

(51) Int. Cl. H01L 29/06; H01L 29/78; H01L 29/739; H01L 29/10; H01L 29/423; H01L 21/265; H01L 21/28; H01L 29/66

(52) U.S. Cl. CPC H01L 29/063; H01L 29/7813; H01L 29/7397; H01L 29/0696; H01L 29/1095; H01L 29/66734; H01L 29/42368; H01L 21/26586; H01L 21/2822; H01L 29/66348; H01L 29/4236

(57) ABSTRACT

A switching element including: a bottom insulating layer disposed at a bottom of a trench; a side surface insulating film covering a side surface of the trench; and a gate electrode disposed inside the trench and insulated from a semiconductor substrate. The semiconductor substrate has a bottom region and a connection region. The bottom region is in contact with the bottom insulating layer. The connection region is in contact with the bottom insulating layer and the side surface insulating film, and connects a body region to the bottom region. An area of the connection region in which the bottom insulating layer contacts to the connection region includes an area with lower a second conductivity-type impurity concentration than a minimum value of the second conductivity-type impurity concentration in an area of the connection region in which the side surface insulating film contacts the connection region.

### BACKGROUND OF THE INVENTION

### 1. Field of the Invention

A technique to be disclosed in this specification relates to a switching element.

### 2. Description of Related Art

Japanese Patent Application Publication No. 2007-242852 discloses a MOSFET. This MOSFET has a semiconductor substrate with trenches formed in an upper surface. Inside the trench, a bottom insulating layer, a side surface insulating film, and a gate electrode are disposed. The bottom insulating layer is disposed at a bottom of the trench, and covers a bottom surface of the trench and a part of a side surface of the trench near the bottom surface. The side surface insulating film is a thin insulating film, and covers the side surface of the trench on an upper side of the bottom insulating layer. The gate electrode is insulated from the semiconductor substrate by the bottom insulating layer and the side surface insulating film. The semiconductor substrate has an n-type source region, a p-type body region, and an n-type drift region. The source region is in contact with the side surface insulating film. The body region is in contact with the side surface insulating film on a lower side of the source region. The drift region is in contact with the side surface insulating film and the bottom insulating layer on a lower side of the body region. The semiconductor substrate further has a p-type bottom region (p-diffusion region extending along the bottom surface of the trench), and a p-type connection region (p-diffusion region extending along the side surface of the trench). The connection region is provided in a part of the side surface of the trench and connects the bottom region and the body region to each other.

When the MOSFET of JP 2007-242852 A turns off, a depletion layer spreads from the body region and the bottom region into the drift region. As the connection region is depleted in the process, the bottom region is electrically separated from the body region. As a result, the potential of the bottom region floats. This prevents a large difference in potential between the bottom region and a rear surface of the semiconductor substrate. Specifically, two peaks of an electric field can be formed respectively at a pn-junction interface between the body region and the drift region and at a pn-junction interface between the bottom region and the drift region, which makes the MOSFET resistant to high voltage.

When the MOSFET of JP 2007-242852 A turns on, a channel (inversion layer) is formed in the body region and the depletion layer having spread into the drift region shrinks, which turns on the MOSFET. In the turn-on process of the MOSFET, the depletion layer inside the connection region also shrinks, so that the bottom region is electrically connected to the body region through the connection region. Then, holes are supplied from the body region to the bottom region. As a result, the depletion layer having spread from the bottom region to the drift region shrinks toward the bottom region. As the depletion layer having spread from the bottom region to the drift region thus shrinks at turn-on, resistance in the drift region decreases. Accordingly, electrons can flow through the drift region with low resistance.

### SUMMARY OF THE INVENTION

FIG. 20 shows an enlarged sectional view of the connection region of the MOSFET of JP 2007-242852 A. As shown in FIG. 20, a connection region 240 extends along the side surface of the trench, and is in contact with a bottom insulating layer 204 and a side surface insulating film 206. The connection region 240 has a part 240a in contact with the side surface insulating film 206 and a part 240b in contact with the bottom insulating layer 204. Due to the necessity of depleting the connection region 240 at turn-off, the MOSFET of JP 2007-242852 A has a low p-type impurity concentration in the connection region 240. To turn on the MOSFET, a gate turn-on potential is applied to a gate electrode 260. Then, electrons are attracted to the vicinity of the side surface insulating film 206 by the electric field acting from the gate electrode 260 on the connection region 240 through the thin side surface insulating film 206. As a result, an inversion layer 210 (a region inverted to an n-type) similar to a channel is formed in the part 240a of the connection region 240. Thus, a width W240 of a region in the part 240a of the connection region 240 that maintains p-type conductivity is reduced. Accordingly, resistance in a hole supply path leading from a body region 220 via the connection region 240 to a bottom region 230 increases. For this reason, at turn-on, holes are slow to be supplied to the bottom region 230, and the depletion layer spreading from the bottom region 230 to the drift region 250 is slow to shrink. Thus, when the MOSFET of JP 2007-242852 A turns on, it takes time before the resistance in the drift region 250 decreases.

While the above description is based on the example of an n-channel MOSFET, the same problem also arises in other switching elements having a gate electrode inside a trench (e.g., a p-channel MOSFET, an IGBT, etc.) when the switching element is provided with a bottom region and a connection region. In the case of a p-channel MOSFET, however, the conductivity types of the regions are opposite from those of an n-channel MOSFET, and electrons are supplied to the bottom region at turn-on.

A switching element to be disclosed by this specification has a semiconductor substrate, a trench, a bottom insulating layer, a side surface insulating film, and a gate electrode. The trench is provided in an upper surface of the semiconductor substrate. The bottom insulating layer is disposed at a bottom of the trench, and covers a bottom surface of the trench and a part of a side surface of the trench near the bottom surface. The side surface insulating film covers the side surface of the trench on an upper side of the bottom insulating layer, and has a thickness smaller than a width between an upper surface and a lower surface of the bottom insulating layer. The gate electrode is disposed inside the trench and insulated from the semiconductor substrate by the bottom insulating layer and the side surface insulating film. The semiconductor substrate has a first region, a body region, a second region, a bottom region, and a connection region. The first region is a region of a first conductivity type in contact with the side surface insulating film. The body region is a region of a second conductivity type in contact with the side surface insulating film on a lower side of the first region. The second region is a region of the first conductivity type in contact with the side surface insulating film and the bottom insulating layer on a lower side of the body region and separated from the first region by the body region. The bottom region is a region of the second conductivity type in contact with the bottom insulating layer at the bottom surface of the trench. The connection region is a region of the second conductivity type extending along the side surface of the trench, in contact with the bottom insulating layer and the side surface insulating film, and connecting the body region and the bottom region to each other. A depth area of the connection region in which the bottom insulating layer and the connection region are in contact with each other includes a depth area with a second conductivity-type impurity concentration lower than a minimum value of the second conductivity-type impurity concentration in a depth area of the connection region in which the side surface insulating film and the connection region are in contact with each other.

The first conductivity type is one of an n-type and a p-type, and the second conductivity type is the other of the n-type and the p-type. If the first conductivity type is the n-type, the second conductivity type is the p-type, and if the first conductivity type is the p-type, the second conductivity type is the n-type.

The above-mentioned second conductivity-type impurity concentration in the connection region (i.e., the second conductivity-type impurity concentration in the depth area of the connection region in which the bottom insulating layer and the connection region are in contact with each other, and the second conductivity-type impurity concentration in the depth area of the connection region in which the side surface insulating film and the connection region are in contact with each other) means a maximum value of the concentration of second conductivity-type impurities distributed at the same depth. Specifically, the second conductivity-type impurities inside the connection region are in most cases distributed at varying concentrations at the same depth, and the above second conductivity-type impurity concentration means the maximum value of the concentration of the second conductivity-type impurities at the same depth.

In this switching element, the depth area of the connection region in which the bottom insulating layer and the connection region are in contact with each other includes the depth area (hereinafter referred to as a specific depth area) with the second conductivity-type impurity concentration lower than the minimum value of the second conductivity-type impurity concentration in the depth area (hereinafter referred to as a first depth area) of the connection region in which the side surface insulating film and the connection region are in contact with each other. In other words, the second conductivity-type impurity concentration in the entire first depth area of the connection region is higher than the second conductivity-type impurity concentration in the specific depth area of the connection region.

When this switching element turns off, a depletion layer spreads from a pn-junction interface between the body region and the second region, and a depletion layer also spreads from a pn-junction interface between the bottom region and the second region. In the turn-off process of the switching element, the specific depth area of the connection region (i.e., an area of the connection region with a low second conductivity-type impurity concentration) is depleted. As a result, the bottom region is electrically separated from the body region, and the potential of the bottom region floats. This prevents a large difference in potential between the bottom region and a lower surface of the semiconductor substrate.

When this switching element turns on, a gate turn-on potential is applied to the gate electrode. Then, a channel (inversion layer) is formed in the body region, and the depletion layer having spread to the second region shrinks toward the body region. In the turn-on process of the MOSFET, the depletion layer shrinks from the specific depth area of the connection region, so that the bottom region is electrically connected to the body region. Since the first depth area of the connection region has a high second conductivity-type impurity concentration, an inversion layer is less likely to be formed in in that area of the connection region even when a gate turn-on potential is applied to the gate electrode. No inversion layer is formed in the first depth area of the connection region, or even if an inversion layer is formed, the width thereof is small. Accordingly, a large width (width corresponding to the width W240 of FIG. 20) of a part of the first depth area of the connection region that maintains the second-type conductivity is secured. For this reason, resistance in a carrier supply path leading from the body region via the connection region to the bottom region is low, and carriers are supplied from the body region to the bottom region at high speed. Accordingly, the depletion layer spreading from the bottom region to the second region shrinks fast. Thus, in this switching element, resistance in the second region decreases in a short time at turn-on. This switching element is therefore less likely to suffer a loss than the conventional one.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a plan view of a MOSFET 10;

FIG. 2 is a longitudinal sectional view (longitudinal sectional view taken along the line II-II of FIG. 1) of the MOSFET 10;

FIG. 3 is a longitudinal sectional view (longitudinal sectional view taken along the line of FIG. 1) of the MOSFET 10;

FIG. 4 is an enlarged view of a connection region 38;

FIG. 5 is a graph showing a p-type impurity concentration distribution in the connection region 38 (more specifically, a distribution of maximum values of a concentration of p-type impurities at respective depths);

FIG. 6 is a view illustrating a manufacturing method of the MOSFET 10;

FIG. 7 is a view illustrating the manufacturing method of the MOSFET 10;

FIG. 8 is a view illustrating the manufacturing method of the MOSFET 10;

FIG. 9 is a view illustrating the manufacturing method of the MOSFET 10;

FIG. 10 is a view illustrating the manufacturing method of the MOSFET 10;

FIG. 11 is a plan view of a MOSFET of a modified example;

FIG. 12 is a plan view of a MOSFET of Embodiment 2;

FIG. 13 is a longitudinal sectional view (longitudinal sectional view taken along the line XIII-XIII of FIG. 12) of the MOSFET of Embodiment 2;

FIG. 14 is a view illustrating a manufacturing method of the MOSFET of Embodiment 2;

FIG. 15 is a view illustrating the manufacturing method of the MOSFET of Embodiment 2;

FIG. 16 is a view illustrating the manufacturing method of the MOSFET of Embodiment 2;

FIG. 17 is a view illustrating the manufacturing method of the MOSFET of Embodiment 2;

FIG. 18 is a plan view of a MOSFET of a modified example;

FIG. 19 is a longitudinal sectional view of a MOSFET of Embodiment 3; and

FIG. 20 is an enlarged view of a connection region of a MOSFET of the related art.

### DETAILED DESCRIPTION OF EMBODIMENTS

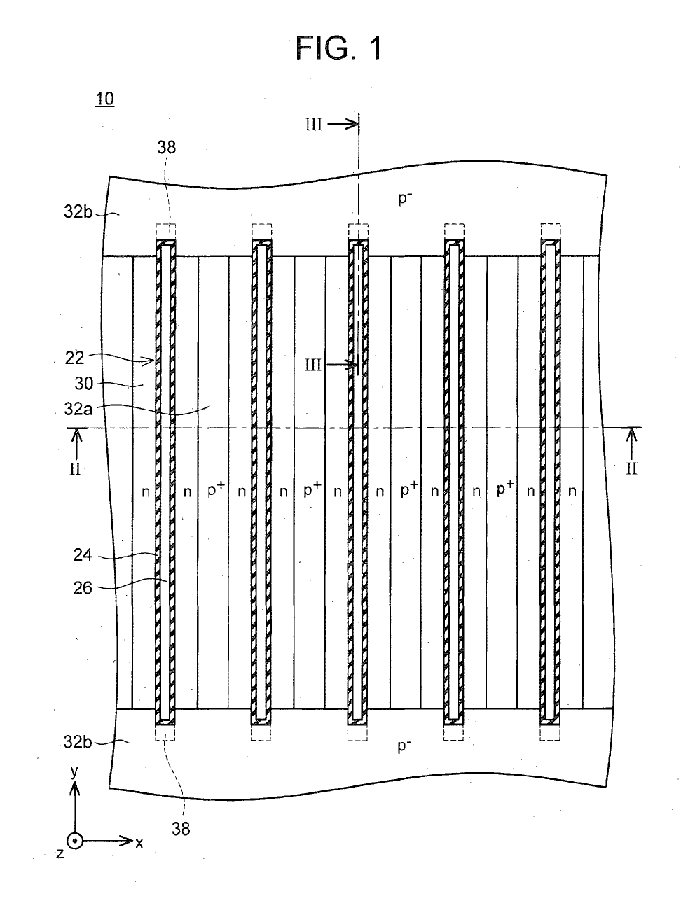

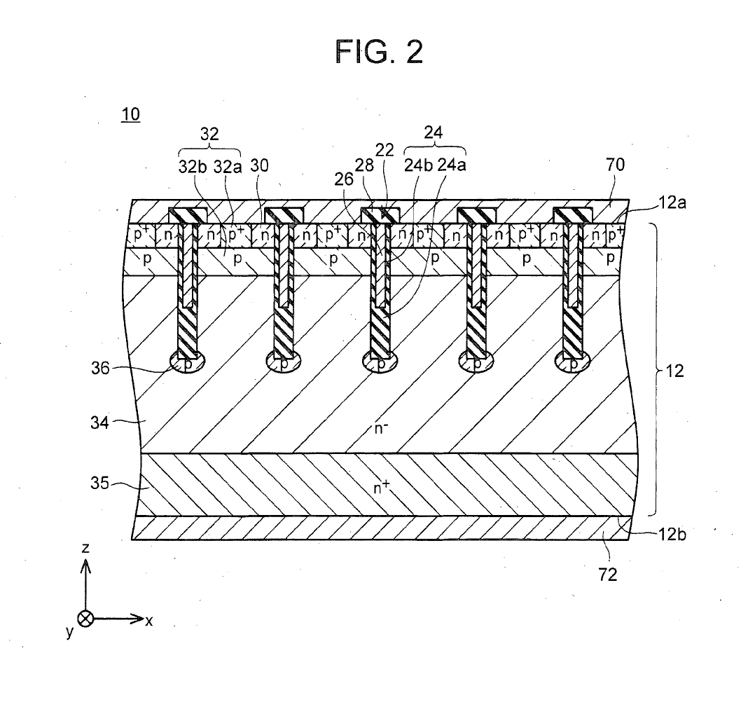

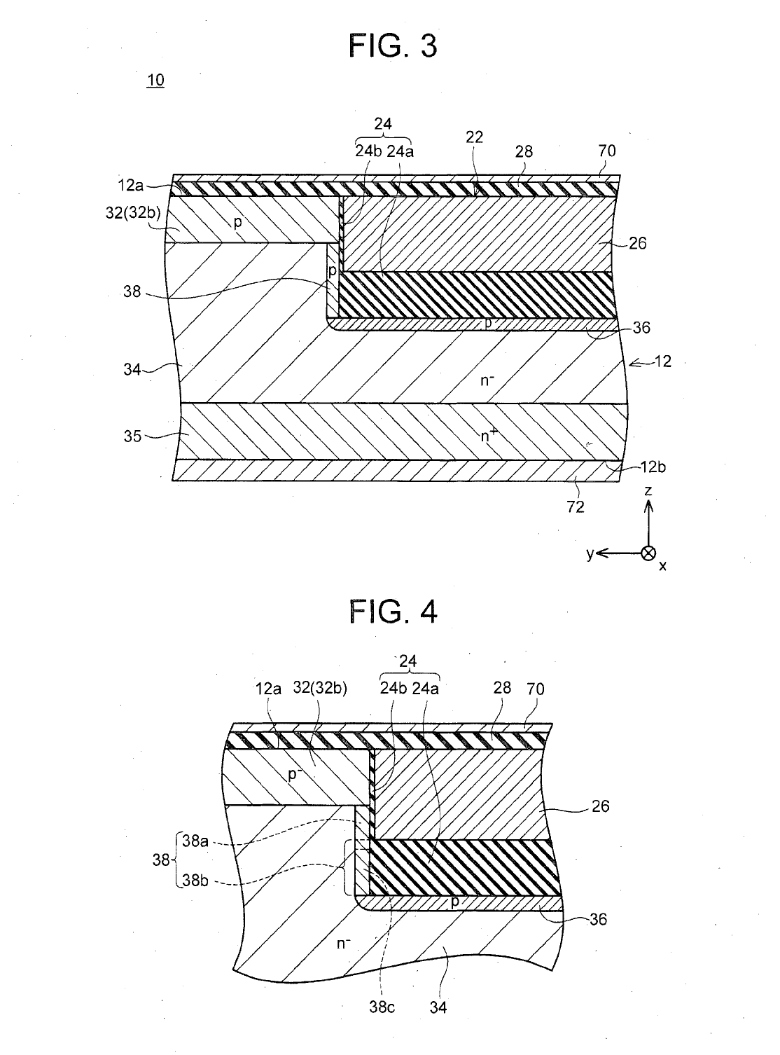

FIGS. 1 to 3 show a MOSFET 10 of Embodiment 1. As shown in FIGS. 2 and 3, the MOSFET 10 includes a semiconductor substrate 12, electrodes, insulating layers, etc. For visibility, an electrode and insulating layers on an upper surface 12a of the semiconductor substrate 12 are not shown in FIG. 1. Hereinafter, a direction parallel to the upper surface 12a of the semiconductor substrate 12 will be referred to as an x-direction; a direction parallel to the upper surface 12a and orthogonal to the x-direction will be referred to as a y-direction; and a thickness direction of the semiconductor substrate 12 will be referred to as a z-direction.

As shown in FIG. 2, a plurality of trenches 22 are provided in the upper surface 12a of the semiconductor substrate 12. As shown in FIG. 1, the trenches 22 extend linearly long in the y-direction. The plurality of trenches 22 are arrayed at intervals in the x-direction. As shown in FIG. 2, an inner surface of the trench 22 is covered by a gate insulating layer 24. The gate insulating layer 24 has a bottom insulating layer 24a and a side surface insulating film 24b. The bottom insulating layer 24a is disposed at a bottom of the trench 22. The bottom insulating layer 24a covers a bottom surface of the trench 22 and a part of a side surface of the trench 22 near the bottom surface. The bottom insulating layer 24a is formed thick in a depth direction of the trench 22. The side surface insulating film 24b covers the side surface of the trench 22 located on an upper side of the bottom insulating layer 24a. A gate electrode 26 is disposed on the upper side of the bottom insulating layer 24a inside the trench 22. Thus, an insulating layer between the gate electrode 26 and the bottom surface of the trench 22 is the bottom insulating layer 24a. The gate electrode 26 is insulated from the semiconductor substrate 12 by the gate insulating layer 24 (i.e., the bottom insulating layer 24a and the side surface insulating film 24b). A thickness of the side surface insulating film 24b (i.e., an interval between the side surface of the trench 22 and a side surface of the gate electrode 26) is smaller than a thickness of the bottom insulating layer 24a (i.e., a width between an upper surface and a lower surface of the bottom insulating layer 24a; in other words, an interval between a lower end of the gate electrode 26 and the bottom surface of the trench 22). An upper surface of the gate electrode 26 is covered by an interlayer insulating film 28.

An upper electrode 70 is disposed on the upper surface 12a of the semiconductor substrate 12. The upper electrode 70 is in contact with the upper surface 12a of the semiconductor substrate 12 at portions where the interlayer insulating film 28 is not provided. The upper electrode 70 is insulated from the gate electrodes 26 by the interlayer insulating films 28. A lower electrode 72 is disposed on a lower surface 12b of the semiconductor substrate 12. The lower electrode 72 is in contact with the lower surface 12b of the semiconductor substrate 12.

As shown in FIGS. 1 to 3, a plurality of source regions 30, a body region 32, a drift region 34, a drain region 35, a plurality of bottom regions 36, and a plurality of connection regions 38 are provided inside the semiconductor substrate 12.

The source regions 30 are n-type regions. As shown in FIGS. 1 and 2, the source region 30 is disposed at a position exposed to the upper surface 12a of the semiconductor substrate 12, and is in ohmic contact with the upper electrode 70. The source region 30 is also in contact with the side surface insulating film 24b at a side surface in a short-side direction of the trench 22 (the side surface located at an end of the trench 22 in the short-side direction and extending along the y-direction). The source region 30 is in contact with the side surface insulating film 24b at an upper end of the trench 22.

The body region 32 is a p-type region. The body region 32 is in contact with the source regions 30. The body region 32 extends from an area between two source regions 30 to a lower side of the source regions 30. The body region 32 has a high-concentration region 32a and a low-concentration region 32b. The high-concentration region 32a has a higher p-type impurity concentration than the low-concentration region 32b. The high-concentration region 32a is disposed in the area between two source regions 30. The high-concentration region 32a is in ohmic contact with the upper electrode 70. The low-concentration region 32b is disposed on a lower side of the high-concentration region 32a and the source regions 30. The low-concentration region 32b is in contact with the side surface insulating films 24b at the side surfaces in the short-side direction of the trenches 22. That is, the low-concentration region 32b is in contact with the side surface insulating films 24b on the lower side of the source regions 30. As shown in FIGS. 1 and 3, the low-concentration region 32b is also disposed in areas adjacent to side surfaces in a long-side direction of the trenches 22 (the side surfaces located at ends of the trenches 22 in the long-side direction and extending along the x-direction). The low-concentration region 32b is in contact with the side surface insulating films 24b at the side surfaces in the long-side direction of the trenches 22. A lower end of the body region 32 (i.e., a lower end of the low-concentration region 32b) is disposed further on an upper side than the lower end of the gate electrode 26 (i.e., the upper surface of the bottom insulating layer 24a).

The drift region 34 is an n-type region. The drift region 34 is disposed on the lower side of the body region 32 and separated from the source regions 30 by the body region 32. The drift region 34 is in contact with the side surface insulating films 24b and the bottom insulating layers 24a at the side surfaces in the short-side direction of the trenches 22. That is, the drift region 34 is in contact with the side surface insulating films 24b and the bottom insulating layers 24a on the lower side of the body region 32.

The drain region 35 is an n-type region. The drain region 35 has a higher n-type impurity concentration than the drift region 34. The drain region 35 is disposed on a lower side of the drift region 34. The drain region 35 is exposed to the lower surface 12b of the semiconductor substrate 12. The drain region 35 is in ohmic contact with the lower electrode 72.

The bottom regions 36 are p-type regions. The bottom region 36 is disposed in an area exposed to the bottom surface of the corresponding trench 22. The bottom region 36 is in contact with the bottom insulating layer 24a at the bottom surface of the corresponding trench 22. As shown in FIG. 3, the bottom region 36 extends long in the y-direction along the bottom surface of the corresponding trench 22. The bottom region 36 is in contact with the bottom insulating layer 24a over the entire bottom surface of the corresponding trench 22. As shown in FIG. 2, a periphery of the bottom region 36 is surrounded by the drift region 34. Except for a portion where a connection region 38, to be described later, is formed, the bottom region 36 is separated from the body region 32 by the drift region 34.

As shown in FIGS. 1 and 3, the connection region 38 is provided along the side surface in the long-side direction of the corresponding trench 22. As shown in FIG. 3, a lower end of the connection region 38 is connected to the corresponding bottom region 36. An upper end of the connection region 38 is connected to the body region 32 (low-concentration region 32b). In this specification, a portion that extends long along the side surface of the trench 22 from the body region 32 toward the bottom region 36 is referred to as the connection region 38. In other words, a p-type region stretching in a lateral direction along the upper surface 12a of the semiconductor substrate 12 is the body region 32, and portions protruding downward from the body region 32 along the side surfaces of the trenches 22 are the connection regions 38. As shown in FIG. 3, the connection region 38 is in contact with the side surface insulating film 24b and the bottom insulating layer 24a at the side surface in the long-side direction of the corresponding trench 22.

FIG. 4 is an enlarged sectional view of the connection region 38. As described above, the connection region 38 is in contact with the side surface insulating film 24b and the bottom insulating layer 24a. A first part 38a shown in FIG. 4 is a depth area of the connection region 38 in which the side surface insulating film 24b and the connection region 38 are in contact with each other. A second part 38b shown in FIG. 4 is a depth area of the connection region 38 in which the bottom insulating layer 24a and the connection region 38 are in contact with each other. The first part 38a is located further on the upper side than the lower end of the gate electrode 26 (i.e., the upper surface of the bottom insulating layer 24a), while the second part 38b is located further on the lower side than the lower end of the gate electrode 26.

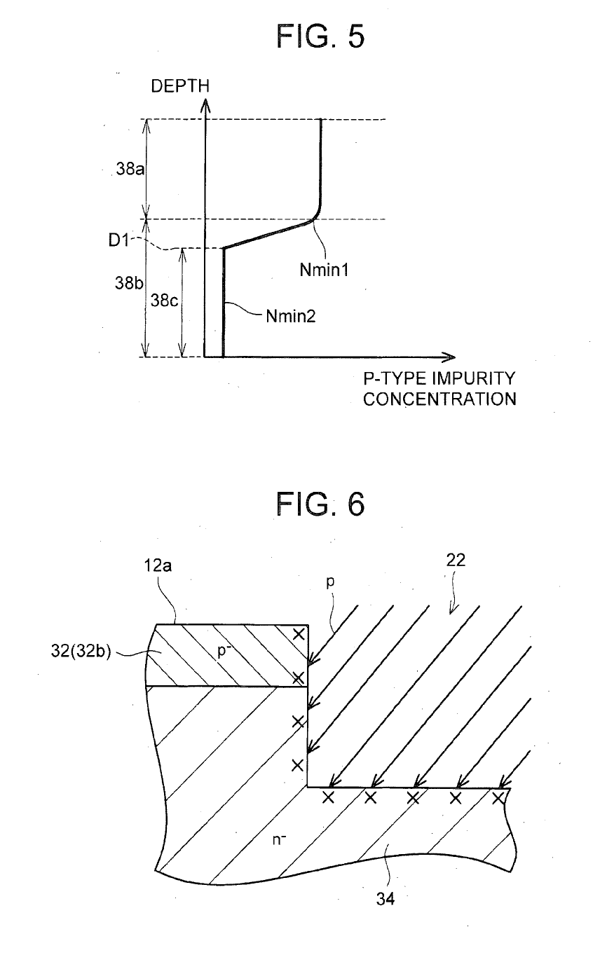

FIG. 5 shows a p-type impurity concentration distribution in a depth direction (z-direction) inside the connection region 38. Inside the connection region 38, the p-type impurities are present at a higher concentration at a position closer to the trench 22 in lateral directions (x-direction and y-direction). The p-type impurity concentration at each depth shown in FIG. 5 represents a maximum value of the concentration of the p-type impurities at the same depth inside the connection region 38. As shown in FIG. 5, the entire depth area of the first part 38a has a high p-type impurity concentration. The p-type impurity concentration in the first part 38a is higher than the p-type impurity concentration in the low-concentration region 32b (i.e., a region where a channel is formed) disposed between the source regions 30 and the drift region 34. The first part 38a has a minimum value Nmin1 of the p-type impurity concentration at a lower end thereof. In this embodiment, the minimum value Nmin1 is adjusted to a value higher than 2×10¹⁸/cm³ so that no inversion layer is formed in the first part 38a in an ON state of the MOSFET 10. In other words, the entire depth area of the first part 38a has a p-type impurity concentration higher than 2×10¹⁸/cm³. The second part 38b has a highest p-type impurity concentration at an upper end thereof. In an area between the upper end and a depth D1, the p-type impurity concentration decreases toward the lower side, while in a part 38c that is a depth area located at a depth greater than the depth D1, the p-type impurity concentration is distributed substantially evenly at a low value. A p-type impurity concentration in the second part 38b is lower than the minimum value Nmin1 at any depth. The part 38c has a minimum value Nmin2 of the p-type impurity concentration in the second part 38b. In this embodiment, to deplete the part 38c in an OFF state of the MOSFET 10, the p-type impurity concentration Nmin2 in the part 38c is adjusted to a value lower than 3×10¹⁷/cm³.

Next, operation of the MOSFET 10 will be described. To use the MOSFET 10, the MOSFET 10, a load (e.g., a motor), and a power source are connected in series. A power source voltage (about 800V in this embodiment) is applied to the series circuit of the MOSFET 10 and the load. This power source voltage is applied in such a direction that a drain side (side of the lower electrode 72) of the MOSFET 10 has a higher potential than a source side (side of the upper electrode 70) thereof. When a gate turn-on potential (potential higher than a gate threshold) is applied to the gate electrode 26, a channel (inversion layer) is formed in an area of the body region 32 (low-concentration region 32b) that is in contact with the side surface insulating film 24b, and the MOSFET 10 turns on. When a gate turn-off potential (potential equal to or lower than the gate threshold) is applied to the gate electrode 26, the channel disappears and the MOSFET 10 turns off. In the following, operation of the MOSFET 10 at turn-off and turn-on will be described in detail.

To turn off the MOSFET 10, the potential of the gate electrode 26 is lowered from the gate turn-on potential to the gate turn-off potential. Then, the channel disappears and the potential of the lower electrode 72 rises. The potential of the lower electrode 72 rises to a potential higher than that of the upper electrode 70 by the power source voltage (i.e., about 800V). While the potential of the lower electrode 72 rises, capacitive coupling between the bottom region 36 and the lower electrode 72 causes a little rise in potential of the bottom region 36. Then, holes flow from the bottom region 36 to the upper electrode 70 through the connection region 38 and the body region 32. As long as the holes are thus flowing, a rise in potential of the bottom region 36 is prevented, and the bottom region 36 is kept at a potential slightly higher than the potential of the upper electrode 70.

As the potential of the lower electrode 72 rises, potentials of the drain region 35 and the drift region 34 also rise. When the potential of the drift region 34 rises, a difference in potential occurs between the body region 32 and the drift region 34. As a result, a reverse voltage is applied to a pn-junction interface between the body region 32 and the drift region 34. Accordingly, a depletion layer spreads from the body region 32 to the drift region 34. Moreover, when the potential of the drift region 34 rises, a difference in potential occurs between the bottom region 36 and the drift region 34. As a result, a reverse voltage is applied to a pn-junction interface between the bottom region 36 and the drift region 34. Accordingly, a depletion layer spreads from the bottom region 36 to the drift region 34.

When the potential of the drift region 34 rises, a reverse voltage is also applied to a pn-junction interface between the connection region 38 and the drift region 34. Since the part 38c of the connection region 38 (see FIGS. 4 and 5) has a low p-type impurity concentration, a depletion layer spreads widely from the pn-junction to the part 38c. Thus, the entire part 38c is depleted. As the part 38c is depleted, the bottom region 36 is electrically separated from the upper electrode 70.

Since the first part 38a of the connection region 38 has a high p-type impurity concentration, a depletion layer is less likely to spread in the first part 38a. Accordingly, the first part 38a is depleted only at a portion near the pn-junction.

When the bottom region 36 is electrically separated from the body region 32, a flow of holes from the bottom region 36 toward the upper electrode 70 stops, so that the potential of the bottom region 36 floats. Accordingly, the potential of the bottom region 36 rises as the potential of the lower electrode 72 rises. This rise in potential of the bottom region 36 prevents an excessively large difference in potential between the bottom region 36 and the lower electrode 72. Specifically, two peaks of an electric field can be formed respectively at the pn-junction interface between the body region 32 and the drift region 34 and at the pn-junction interface between the bottom region 36 and the drift region 34, which makes the MOSFET 10 resistant to high voltage. Turning off of the MOSFET 10 is completed when the potential of the lower electrode 72 has risen to a potential higher than that of the upper electrode 70 by the power source voltage.

To turn on the MOSFET 10, the potential of the gate electrode 26 is raised from the gate turn-off potential to the gate turn-on potential. Then, electrons are attracted to an area of the body region 32 (low-concentration region 32b) that is in contact with the side surface insulating films 24b at the side surfaces in the short-side direction of the trenches 22. Thus, this area of the body region 32 is inverted from the p-type to the n-type, and a channel is formed. This channel connects the source regions 30 and the drift region 34 to each other. As a result, the potentials of the drift region 34, the drain region 35, and the lower electrode 72 decrease. When the potential of the drift region 34 decreases, the reverse voltage having been applied to the pn-junction interface between the body region 32 and the drift region 34 decreases. Accordingly, the depletion layer having spread from the body region 32 to the drift region 34 shrinks toward the body region 32. Thus, electrons start to flow from the upper electrode 70 via the source regions 30, the channel, the drift region 34, and the drain region 35 to the lower electrode 72. In other words, the MOSFET 10 turns on.

Since the first part 38a of the connection region 38 has a high p-type impurity concentration, no inversion layer is formed in the first part 38a even when the potential of the gate electrode 26 is raised to the gate turn-on potential. Since the second part 38b of the connection region 38 is at a distance from the gate electrode 26, no inversion layer is formed in the second part 38b, either. While the potential of the drift region 34 decreases, the depletion layer spreading in the part 38c of the connection region 38 shrinks toward the drift region 34. As a result, the bottom region 36 is electrically connected to the body region 32. Then, holes flow from the upper electrode 70 to the bottom region 36 through the body region 32 and the connection region 38. When holes are supplied to the bottom region 36, the depletion layer having spread from the bottom region 36 to the drift region 34 shrinks toward the bottom region 36. Accordingly, resistance in the drift region 34 decreases, and electrons can easily flow from the upper electrode 70 toward the lower electrode 72. Thus, the drift region 34 is less likely to cause a loss. In particular, in this embodiment, with no inversion layer formed in the connection region 38, holes can flow throughout the connection region 38 in the width direction and resistance in the connection region 38 to the holes is low. For this reason, the holes can be supplied to the bottom region 36 at high speed, and the depletion layer having spread from the bottom region 36 to the drift region 34 disappears at high speed. Thus, in the MOSFET 10, resistance in the drift region 34 decreases in a short time after the potential of the gate electrode 26 is raised to the gate turn-on potential. In other words, turn-on resistance decreases in a short time at turn-on of the MOSFET 10. The MOSFET 10 is therefore less likely to suffer a loss.

As has been described above, in the MOSFET 10 of Embodiment 1, the potential of the bottom region 36 floats while the potential of the lower electrode 72 rises at turn-off, which prevents a large difference in potential between the bottom region 36 and the lower electrode 72. Therefore, the MOSFET 10 has high voltage resistance. Moreover, with no inversion layer formed in the connection region 38 at turn-on, the depletion layer spreading from the bottom region 36 to the drift region 34 disappears in a short time. Therefore, the MOSFET 10 is less likely to suffer a loss.

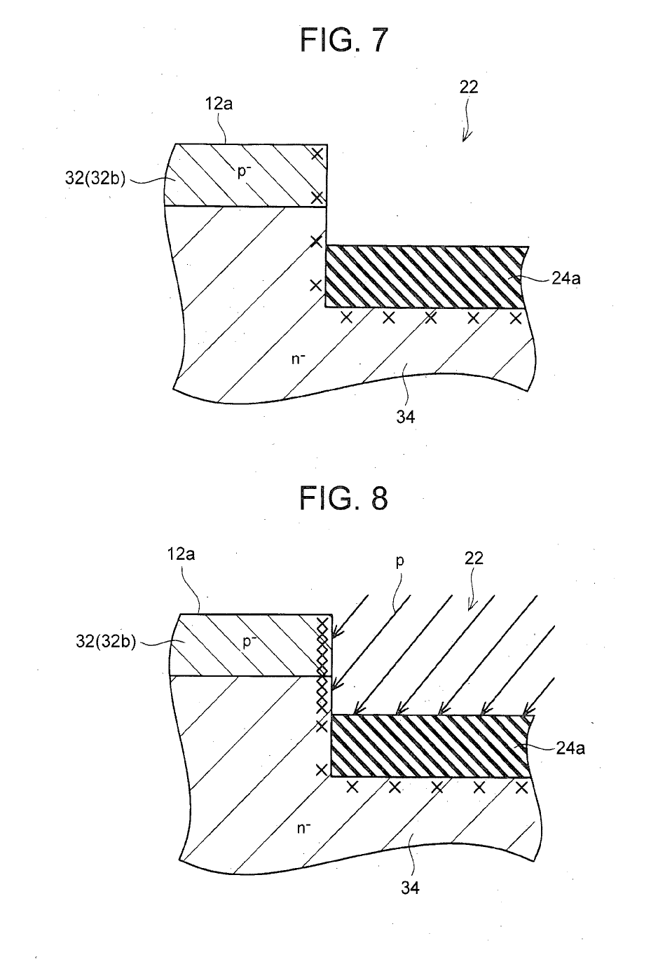

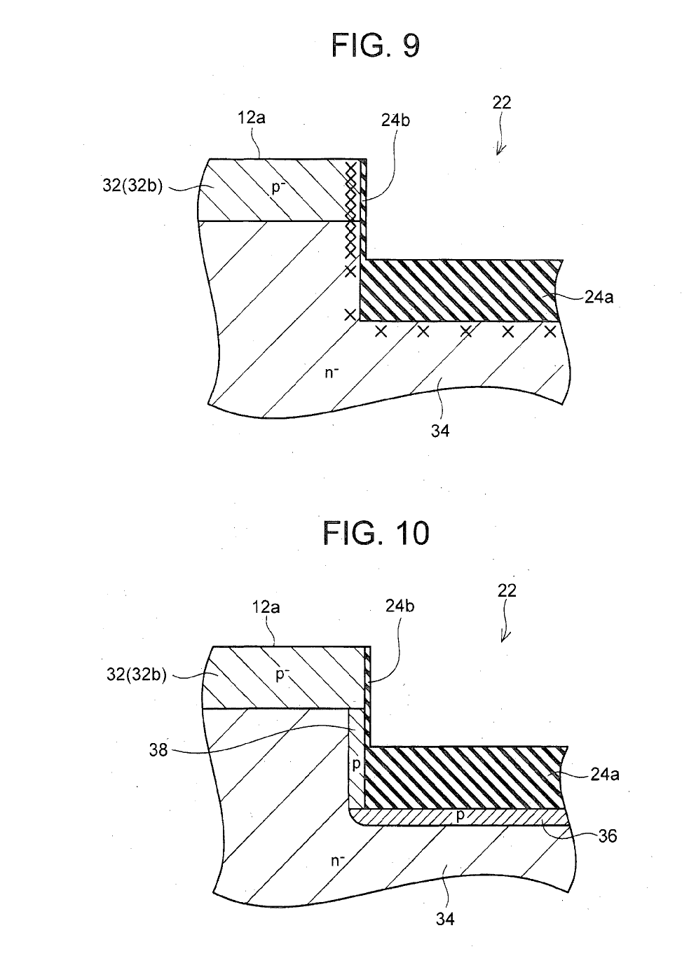

Next, a manufacturing method of the MOSFET 10 of Embodiment 1 will be described. First, an unprocessed semiconductor substrate 12 is prepared. The unprocessed semiconductor substrate 12 is composed of an n-type semiconductor having the drift region 34 and the drain region 35. First, the low-concentration regions 32b of the body region 32 are formed by epitaxial growth or ion injection. Next, the source regions 30 and the high-concentration regions 32a are formed. Then, the trenches 22 are formed as shown in FIG. 6 by partially etching the upper surface 12a of the semiconductor substrate 12. Next, p-type impurities are injected into the semiconductor substrate 12 as shown in FIG. 6. Here, the semiconductor substrate 12 is irradiated with the p-type impurities along a direction inclined relative to the thickness direction (z-direction) of the semiconductor substrate 12. Thus, the p-type impurities are injected into the bottom surface and the side surface in the long-side direction of the trench 22. Next, the p-type impurities are injected with the impurity irradiation direction inclined to the opposite side from FIG. 6. Thus, the p-type impurities are injected into the side surface in the long-side direction of the trench 22 on the opposite side from FIG. 6. Next, an insulating layer is packed inside the trench 22, and then this insulating layer is etched. Here, the insulating layer is left at the bottom of the trench as shown in FIG. 7. This remaining insulating layer forms the bottom insulating layer 24a. Here, etching is performed so that the upper surface of the bottom insulating layer 24a is located further on the lower side than the lower end of the low-concentration region 32b. Next, the p-type impurities are injected into the semiconductor substrate 12 as shown in FIG. 8. Here, as in FIG. 6, the semiconductor substrate 12 is irradiated with the p-type impurities along a direction inclined relative to the thickness direction (z-direction) of the semiconductor substrate 12. Thus, the p-type impurities are injected into the side surface in the long-side direction of the trench 22 (the side surface on the upper side of the bottom insulating layer 24a). Next, the p-type impurities are injected with the impurity irradiation direction inclined to the opposite side from FIG. 8. Thus, the p-type impurities are injected into the side surface in the long-side direction of the trench 22 (the side surface on the upper side of the bottom insulating layer 24a) on the opposite side from FIG. 8. With the p-type impurities thus injected, the p-type impurity concentration becomes higher in the side surfaces (the side surfaces in the long-side direction) on the upper side of the bottom insulating layer 24a than in the areas of the side surfaces covered by the bottom insulating layer 24a. Next, as shown in FIG. 9, the side surface insulating film 24b is formed on the side surface of the trench 22. Thereafter, heat treatment is performed on the semiconductor substrate 12 to activate the p-type impurities injected into the semiconductor substrate 12. Thus, the bottom region 36 and the connection region 38 are formed as shown in FIG. 10. As described above, in the side surfaces in the long-side direction of the trench 22, the side surfaces on the upper side of the bottom insulating layer 24a is injected with the p-type impurities at a higher concentration than the areas of the side surfaces covered by the bottom insulating layer 24a. In this way, the connection region 38 with the distribution of the p-type impurity concentration as shown in FIG. 5 can be formed. Thereafter, the gate electrodes 26, the interlayer insulating films 28, the upper electrode 70, and the lower electrode 72 are formed to complete the MOSFET 10 shown in FIGS. 1 to 3.

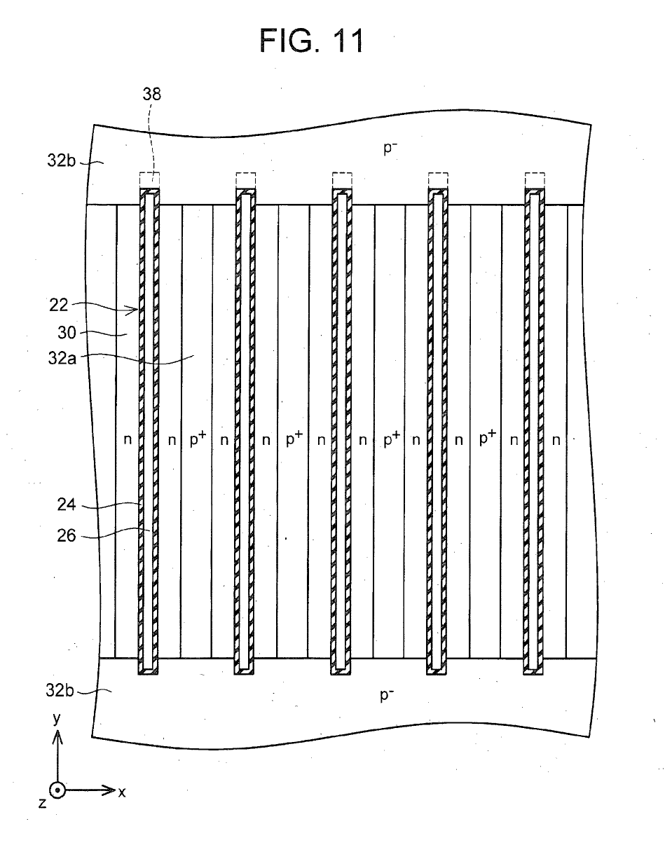

In Embodiment 1 described above, the connection regions 38 are formed on the side surfaces at both sides in the long-side direction of the trenches 22. Alternatively, the connection regions 38 may be formed on the side surfaces at only one side in the long-side direction of the trenches 22 as shown in FIG. 11.

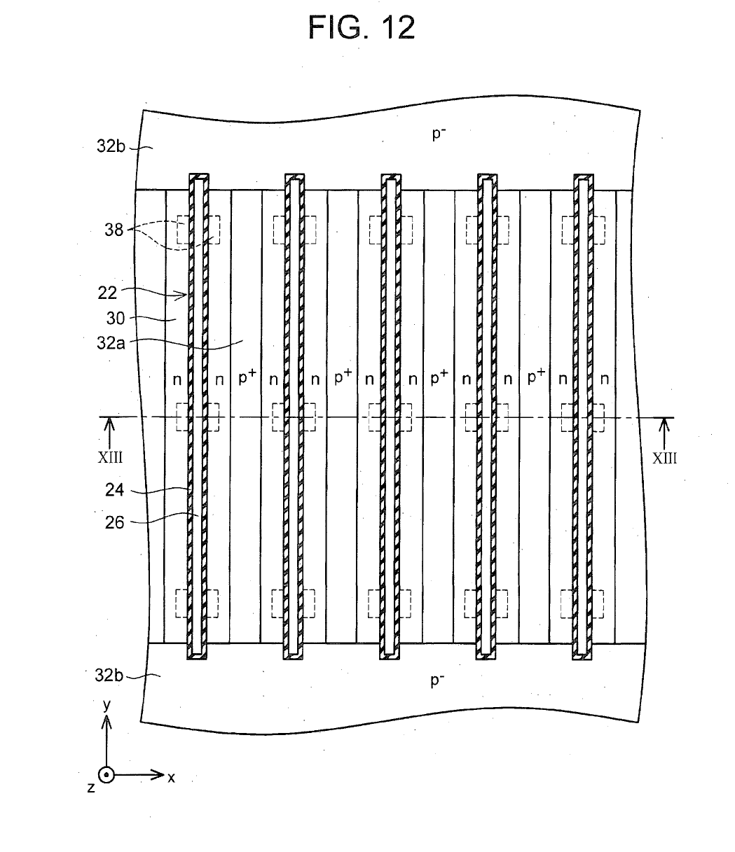

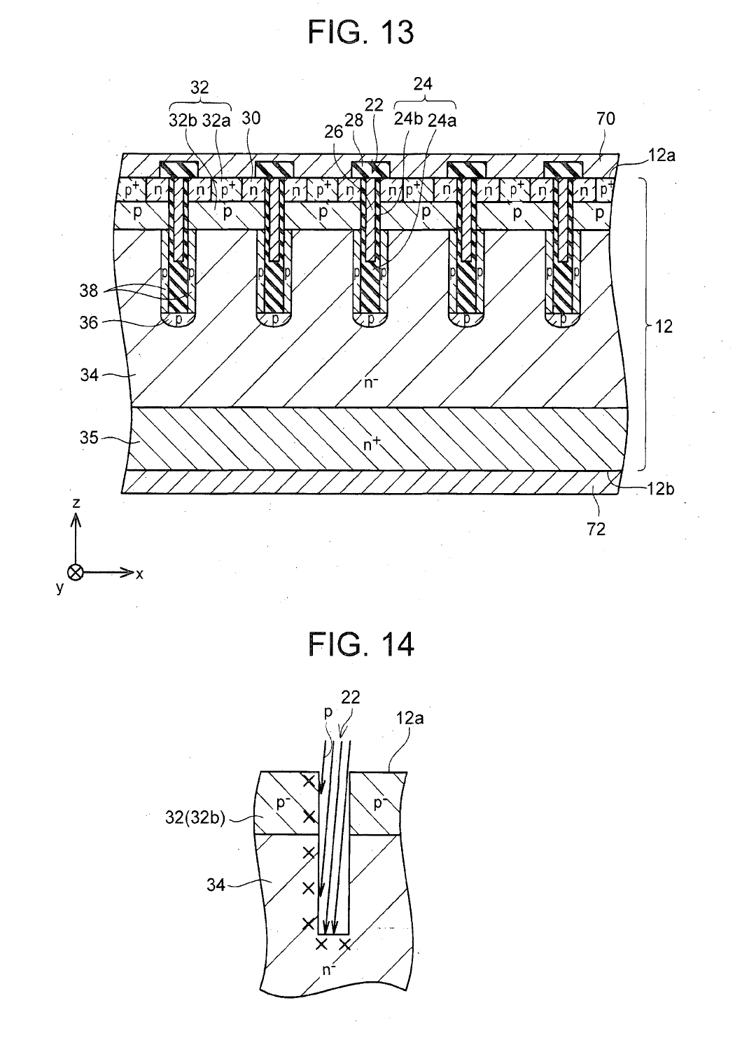

In Embodiment 2, the connection regions 38 are formed in portions of the side surfaces in the short-side direction of the trenches 22 as shown in FIGS. 12 and 13. In Embodiment 2, too, the connection region 38 has a p-type impurity concentration distribution similar to that of FIG. 5. The configuration of a MOSFET of Embodiment 2 is otherwise the same as in Embodiment 1. Even when the connection regions 38 are disposed as in Embodiment 2, the connection regions 38 function substantially the same as in Embodiment 1.

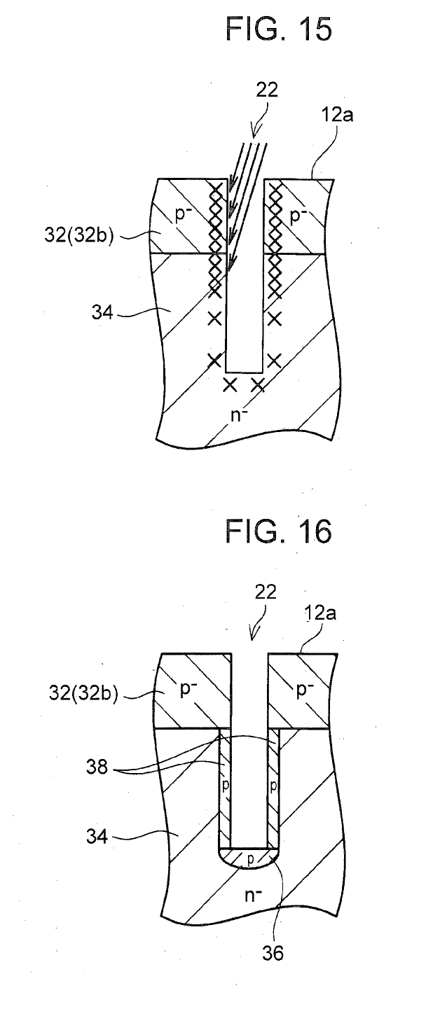

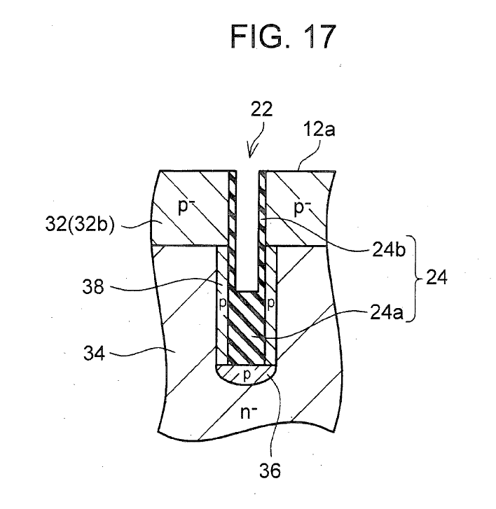

Next, a manufacturing method of the MOSFET of Embodiment 2 will be described. First, the low-concentration regions 32b, the source regions 30, the high-concentration regions 32a, and the trenches 22 are formed in the same manner as the manufacturing method of Embodiment 1. Next, p-type impurities are injected into the semiconductor substrate 12 as shown in FIG. 14. Although this is not shown, areas of the side surfaces of the trench 22 where the connection region 38 is not to be formed are covered with a mask. Here, the semiconductor substrate 12 is irradiated with the p-type impurities along a direction inclined relative to the thickness direction (z-direction) of the semiconductor substrate 12 to inject the p-type impurities into the bottom surface and the side surface (the area of the side surface not covered by the mask) in the short-side direction of the trench 22. Next, the p-type impurities are injected with the impurity irradiation direction inclined to the opposite side from FIG. 14. Thus, the p-type impurities are injected into the side surface in the short-side direction of the trench 22 on the opposite side from FIG. 14. Next, the p-type impurities are injected again, with the p-type impurity irradiation direction inclined at a larger angle as shown in FIG. 15. Here, the p-type impurities are injected into an upper part of the side surface in the short-side direction of the trench 22. The p-type impurities are not injected into the bottom surface and a lower part of the side surface in the short-side direction of the trench 22. Next, the p-type impurities are injected with the impurity irradiation direction inclined to the opposite side from FIG. 15. Thus, the p-type impurities are injected into the side surface in the short-side direction of the trench 22 on the opposite side from FIG. 15. With the p-type impurities thus injected, the p-type impurity concentration becomes higher in the upper part of the side surface in the short-side direction than in the lower part of the side surface in the short-side direction as shown in FIG. 15. Next, heat treatment is performed on the semiconductor substrate 12 to activate the p-type impurities injected into the semiconductor substrate 12. Thus, the bottom region 36 and the connection region 38 are formed as shown in FIG. 16. As described above, the p-type impurity concentration is higher in the upper part than in the lower part of the side surface in the short-side direction of the trench 22. Accordingly, the connection region 38 with the distribution of the p-type impurity concentration as shown in FIG. 5 can be formed. Thereafter, the bottom insulating layer 24a and the side surface insulating film 24b are formed as shown in FIG. 17. Here, the upper surface of the bottom insulating layer 24a is disposed further on the upper side than a lower end of an area of the connection region 38 with a high p-type impurity concentration (i.e., a lower end of the injection area of the p-type impurities shown in FIG. 15). Thereafter, the gate electrodes 26, the interlayer insulating films 28, the upper electrode 70, and the lower electrode 72 are formed to complete the MOSFET of Embodiment 2.

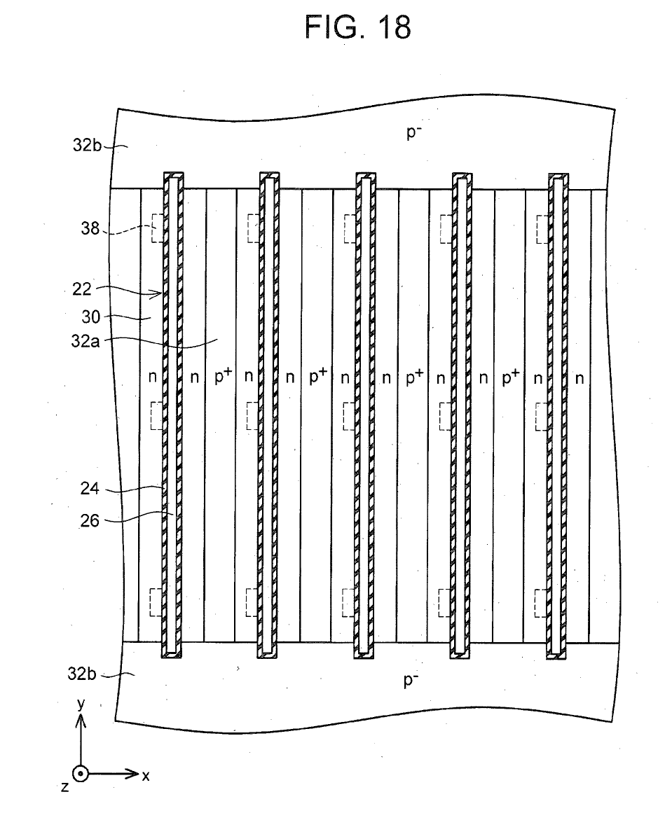

In Embodiment 2 described above, the connection regions 38 are formed on the side surfaces at both sides in the short-side direction of the trenches 22. Alternatively, the connection regions 38 may be formed on the side surfaces at only one side in the short-side direction of the trenches 22 as shown in FIG. 18.

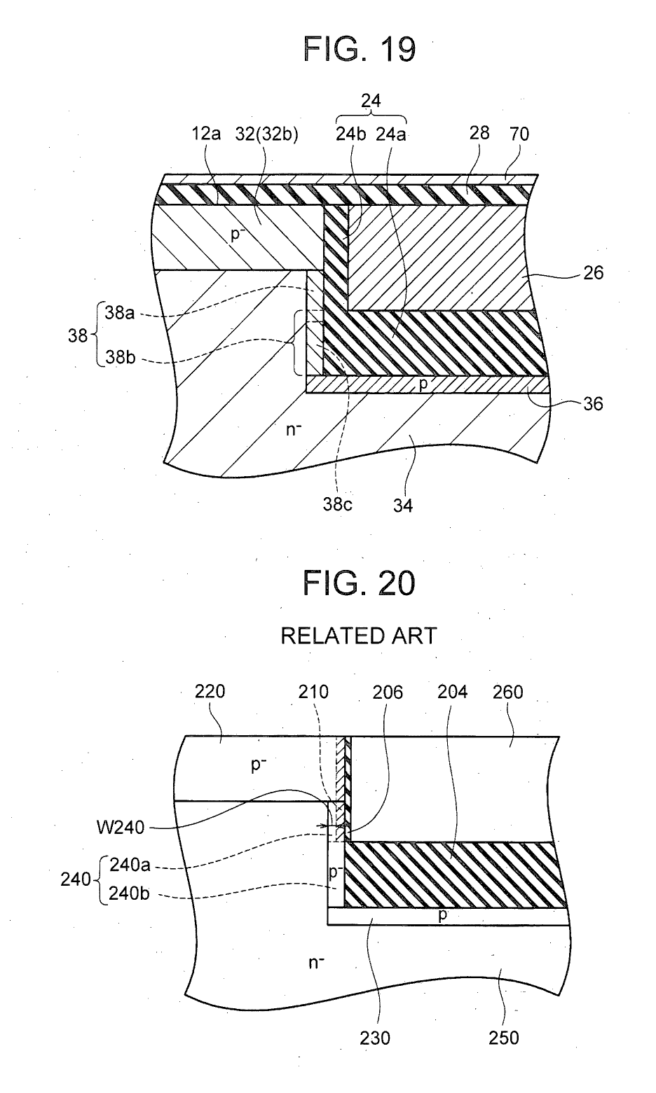

In Embodiment 1 described above, a thickness of the side surface insulating film 24b covering the side surface in the long-side direction of the trench 22 is equal to a thickness of the side surface insulating film 24b covering the side surface in the short-side direction of the trench 22. In a MOSFET of Embodiment 3, by contrast, the thickness of the side surface insulating film 24b covering the side surface in the long-side direction of the trench 22 is large as shown in FIG. 19. In the MOSFET of Embodiment 3, the thickness of the side surface insulating film 24b covering the side surface in the short-side direction of the trench 22 is almost as thin as that of FIG. 3. That is, the thickness of the side surface insulating film 24b covering the side surface in the long-side direction of the trench 22 is larger than the thickness of the side surface insulating film 24b covering the side surface in the short-side direction of the trench 22. In other words, the thickness of a part of the side surface insulating film 24b in contact with the connection region 38 is larger than the thickness of a part of the side surface insulating film 24b in contact with the drift region 34. If the thickness of the part of the side surface insulating film 24b in contact with the connection region 38 is thus large, the first part 38a of the connection region 38 is less likely to be affected by an electric field caused by the potential of the gate electrode 26. Thus, according to this configuration, an inversion layer is even less likely to be formed in the first part 38a.

In the configuration of Embodiment 2, the thickness of the part of the side surface insulating film 24b in contact with the connection region 38 may be made larger than the thickness of the part of the side surface insulating film 24b in contact with the drift region 34. In this configuration, too, an inversion layer is less likely to be formed in the first part 38a.

In Embodiments 1 to 3 described above, no inversion layer is formed in the first part 38a of the connection region 38 at turn-on of the MOSFET 10. However, an inversion layer may be formed in the first part 38a. Since the first part 38a has a high p-type impurity concentration, any inversion layer formed in the first part 38a would have a smaller width than in a conventional switching element. With a larger part of the first part 38a maintaining p-type conductivity, resistance in the connection region 38 to holes is not so high. In this configuration, too, the depletion layer spreading from the bottom region 36 to the drift region 34 disappears in a shorter time than in the related art.

In Embodiments 1 to 3 described above, the n-channel MOSFET has been described. However, the technique disclosed in this specification may be applied to other switching elements. For example, the technique disclosed in this specification may be applied to a p-channel MOSFET or an IGBT. A p-channel MOSFET can be obtained by reversing the n-type regions and the p-type regions of the MOSFET of the above embodiments. An IGBT can be obtained by providing the MOSFET of the above embodiments with a p-type collector region in place of the n-type drain region 35.

In Embodiments 1 to 3 described above, the p-type impurity concentration in the entire second part 38b is lower than the minimum value Nmin1 of the p-type impurity concentration in the first part 38a. However, the p-type impurity concentration may be higher than the minimum value Nmin1 in some depth area of the second part 38b. In this configuration, too, the depth area of the second part 38b with a p-type impurity concentration lower than the minimum value Nmin1 is depleted, so that the bottom region 36 can be electrically separated from the body region 32.

In the embodiments described above, the source region 30 of Embodiments 1 to 3 is one example of the “first region.” The drift region 34 of Embodiments 1 to 3 is one example of the “second region.” The first part 38a of the connection region 38 of Embodiments 1 to 3 is one example of the “depth area of the connection region in which the side surface insulating film and the connection region are in contact with each other.” The second part 38b of the connection region 38 of Embodiments 1 to 3 is one example of the “depth area of the connection region in which the bottom insulating layer and the connection region are in contact with each other.”

A technical element disclosed by this specification will be described below. The following technical element is independently useful.

In a configuration of one example disclosed by this specification, the area of the side surface insulating film in contact with the connection region is thicker than the area of the side surface insulating film in contact with the second region.

According to this configuration, an inversion layer is less likely to be formed due to the depth area of the connection region in which the side surface insulating film and the connection region are in contact with each other.

While the embodiments have been described in detail above, these embodiments are merely examples and do not limit the scope of claims. The technique described in the scope of claims includes various modifications and changes made to the specific examples illustrated above. The technical elements described in this specification or the drawings exhibit their technical usefulness independently or in various combinations, without the combinations being limited to those described in the claims at the time of application. Moreover, the technique illustrated in this specification or the drawings achieves a plurality of purposes at the same time, and is deemed technically useful simply by achieving one of these purposes.

1. A switching element comprising:
a semiconductor substrate;
a trench provided in an upper surface of the semiconductor substrate;
a bottom insulating layer disposed at a bottom of the trench, and covering a bottom surface of the trench and a part of a side surface of the trench near the bottom surface;
a side surface insulating film covering the side surface of the trench on an upper side of the bottom insulating layer and having a thickness smaller than a width between an upper surface and a lower surface of the bottom insulating layer; and
a gate electrode disposed inside the trench and insulated from the semiconductor substrate by the bottom insulating layer and the side surface insulating film, wherein
the semiconductor substrate has:
a first region of a first conductivity type in contact with the side surface insulating film;
a body region of a second conductivity type in contact with the side surface insulating film on a lower side of the first region;
a second region of the first conductivity type in contact with the side surface insulating film and the bottom insulating layer on a lower side of the body region and separated from the first region by the body region;
a bottom region of the second conductivity type in contact with the bottom insulating layer at the bottom surface of the trench; and
a connection region of the second conductivity type extending along the side surface of the trench, in contact with the bottom insulating layer and the side surface insulating film, and connecting the body region and the bottom region to each other, and
a depth area of the connection region in which the bottom insulating layer and the connection region are in contact with each other includes a depth area with a second conductivity-type impurity concentration lower than a minimum value of the second conductivity-type impurity concentration in a depth area of the connection region in which the side surface insulating film and the connection region are in contact with each other.

2. The switching element according to claim 1, wherein an area of the side surface insulating film in contact with the connection region is thicker than an area of the side surface insulating film in contact with the second region.

3. The switching element according to claim 1, wherein the minimum value of the second conductivity-type impurity concentration in the depth area of the connection region in which the side surface insulating film and the connection region are in contact with each other is set to such a value that, in a state where a gate turn-on potential is applied to the gate electrode, no inversion layer is formed in the depth area of the connection region in which the side surface insulating film and the connection region are in contact with each other.

4. The switching element according to claim 3, wherein the second conductivity-type impurity concentration in the depth area of the connection region in which the bottom insulating layer and the connection region are in contact with each other is set so that, in a state where a gate turn-off potential is applied to the gate electrode, a depleted part is formed in the depth area of the connection region in which the side surface insulating film and the connection region are in contact with each other.
